(19) United States
(12) Patent Application Publication
(10) Pub. No.: US 2026/0304742 A1
(43) Pub. Date: Oct. 1, 2026

(54) MEMORY DEVICE AND METHOD FOR FORMING THE SAME

(71) Applicant: NANYA TECHNOLOGY CORPORATION, New Taipei City (TW)

(72) Inventor: Hsuan Han CHEN, New Taipei City (TW)

(21) Appl. No.: 19/093,268

(22) Filed: Mar. 28, 2025

(51) Int. Cl. H10B 12/00

(52) U.S. Cl. CPC H10B 12/315; H10B 12/033; H10B 12/053; H10B 12/34

(57) ABSTRACT

A memory device includes a substrate and a capacitor structure over the substrate. The capacitor structure includes a bottom electrode, a dielectric structure over the bottom electrode, and a top electrode over the dielectric structure. The dielectric structure includes a bottom barrier layer made of aluminum oxide, a top barrier layer made of aluminum oxide over the bottom barrier layer, and a stack of dielectric layers made of zirconium-doped hafnium oxide and at least one inserting layer made of aluminum oxide between the bottom barrier layer and the top barrier layer, wherein the at least one inserting layer is between adjacent two of the dielectric layers.

### BACKGROUND

To support the data retention (tᵣₑₜₑₙₜᵢₒₙ) improvement of dynamic random-access memory (DRAM), the high dielectric constant (ε) for cell and low cell stack leakage (I_{L}) are necessary. In addition, the DRAM cell leakage current increases and capacitance (Cₛ) decreases due to the device scaling. In order to solve the leakage problem and gain the capacitance of the cell for future trend, the present disclosure provides a new structure and higher dielectric constant material.

### SUMMARY

Embodiments of the present disclosure provide a memory device, comprising a substrate and a capacitor structure over the substrate. The capacitor structure includes a bottom electrode, a dielectric structure over the bottom electrode, and a top electrode over the dielectric structure. The dielectric structure includes a bottom barrier layer made of aluminum oxide, a top barrier layer made of aluminum oxide over the bottom barrier layer, and a stack of dielectric layers made of zirconium-doped hafnium oxide and at least one inserting layer made of aluminum oxide between the bottom barrier layer and the top barrier layer, wherein the at least one inserting layer is between adjacent two of the dielectric layers.

In some embodiments, a zirconium concentration of the dielectric layers is from about 50% to about 100%.

In some embodiments, the bottom barrier layer and the top barrier layer are in contact with the bottom electrode and the top electrode, respectively.

In some embodiments, the bottom electrode and the top electrode are made of titanium nitride.

In some embodiments, the bottom electrode is made of polysilicon, and the top electrode is made of titanium nitride.

In some embodiments, the memory device further comprising a silicon oxide layer between the bottom electrode and the bottom barrier layer.

In some embodiments, the bottom barrier layer and the top barrier layer are thicker than the at least one inserting layer.

In some embodiments, the dielectric structure comprises a plurality of inserting layers, wherein each of the plurality of inserting layers is between adjacent two of the dielectric layers.

In some embodiments, the dielectric layers have crystalline structures with tetragonal phase and orthorhombic phase.

In some embodiments, the memory device further comprising: a word line structure over the substrate; and a bit line structure over the substrate and electrically connected to a doped region of the substrate on a first side of the word line structure, wherein the capacitor structure is electrically connected to another doped region of the substrate on a second side of the word line structure.

Embodiments of the present disclosure provide a method for forming a memory device, comprising: forming a capacitor structure over a substrate, comprising: forming a bottom electrode; forming a dielectric structure over the bottom electrode, comprising: forming a bottom barrier layer made of aluminum oxide; forming a stack of dielectric layers made of zirconium-doped hafnium oxide and at least one inserting layer made of aluminum oxide over the bottom barrier layer, wherein the at least one inserting layer is between adjacent two of the dielectric layers; and forming a top barrier layer made of aluminum oxide over the stack of the dielectric layers and the at least one inserting layer; and forming a top electrode over the dielectric structure.

In some embodiments, a zirconium concentration of the dielectric layers is from about 50% to about 100%.

In some embodiments, the bottom barrier layer and the top barrier layer are in contact with the bottom electrode and the top electrode, respectively.

In some embodiments, the bottom electrode and the top electrode are made of titanium nitride.

In some embodiments, the bottom electrode is made of polysilicon, and the top electrode is made of titanium nitride.

In some embodiments, the method further comprising: oxidizing a portion of the bottom electrode into an oxide layer.

In some embodiments, the oxide layer includes silicon oxide.

In some embodiments, forming the bottom barrier layer comprises performing an ALD process by providing an oxygen source and an aluminum source, and wherein the oxygen source oxidizes a portion of the bottom electrode into an oxide layer.

In some embodiments, the bottom barrier layer and the top barrier layer are thicker than the at least one inserting layer.

In some embodiments, the method further comprising: forming a word line structure over the substrate; and forming a bit line structure over the substrate and electrically connected to a doped region of the substrate on a first side of the word line structure, wherein the capacitor structure is electrically connected to another doped region of the substrate on a second side of the word line structure.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIGS. 1-3 are schematic diagrams depicting capacitor structures according to some embodiments of the present disclosure.

FIG. 4 is a circuit diagram of a memory cell of a memory device according to some embodiments of the present disclosure.

FIG. 5 is a cross-sectional view of a memory device according to some embodiments of the present disclosure.

FIGS. 6 to 14 are cross-sectional views at various stages of forming a memory device according to some embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

As used herein, “around”, “about”, “approximately”, or “substantially” may generally mean within 20 percent, or within 10 percent, or within 5 percent of a given value or range. Numerical quantities given herein are approximate meaning that the term “around”, “about”, “approximately”, or “substantially” can be inferred if not expressly stated. One skilled in the art will realize, however, that the values or ranges recited throughout the description are merely examples, and may be reduced or varied with the sown-scaling of the integrated circuits.

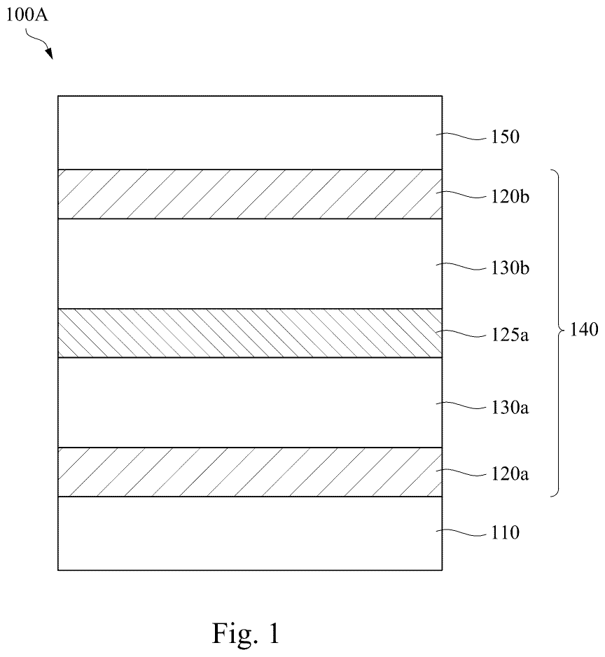

FIG. 1 is a schematic diagram depicting a capacitor structure according to some embodiments of the present disclosure. Referring to FIG. 1, a capacitor structure 100A includes a bottom electrode 110, a dielectric structure 140 over the bottom electrode 110, and a top electrode 150 over the dielectric structure 140. In some embodiments, a material of the bottom electrode 110 may be the same as a material of the top electrode 150. For example, the bottom electrode 110 and the top electrode 150 may include titanium nitride (TiN). In other embodiments, the material of the bottom electrode 110 may be different from the material of the top electrode 150.

The dielectric structure 140 may be a multi-layer structure where a plurality of dielectric layers are stacked. The dielectric structure 140 in the capacitor structure 100A may include a barrier layer 120a, a dielectric layer 130a over the barrier layer 120a, an inserting layer 125a over the dielectric layer 130a, a dielectric layer 130b over the inserting layer 125a, and a barrier layer 120b over the dielectric layer 130b. As shown in FIG. 1, the dielectric layer 130a and the dielectric layer 130b may be separated in a vertical direction by the inserting layer 125a. Furthermore, the barrier layers 120a and 120b are adjacent to and in contact with the bottom electrode 110 and the top electrode 150, respectively.

In some embodiments, the barrier layer 120a, the barrier layer 120b, and the inserting layer 125a may include the same high-k dielectric material, such as aluminum oxide (AlOₓ). In some embodiments, the dielectric layer 130a and the dielectric layer 130b may include the same high-k dielectric material, such as hafnium oxide (HfO₂). In some embodiments, the dielectric layer 130a and the dielectric layer 130b (e.g., HfO₂) may be doped with zirconium (Zr) at a concentration between about 50% to about 100% (e.g., 70%). In some embodiments, the barrier layer 120a, the barrier layer 120b, and the inserting layer 125a may be free of zirconium. That is, the zirconium concentration in the barrier layer 120a, the barrier layer 120b, and the inserting layer 125a may be lower than the zirconium concentration in the dielectric layer 130a and the dielectric layer 130b.

Each of the dielectric layer 130a and the dielectric layer 130b have crystalline structures with orthogonal phase and tetragonal phase. In some embodiments, by doping the dielectric layer 130a and the dielectric layer 130b with zirconium, each of the dielectric layer 130a and the dielectric layer 130b include an orthogonal phase and a tetragonal phase with a certain ratio, which can also be referred to as a morphotropic phase boundary (MPB). With such configuration can gain the condition equivalent oxide thickness (EOT) due to the higher k-value to achieve an increasing capacitance and to reduce leakage current.

The fabrication method results in the capacitor structure 100A will be described in further detail below. As shown in FIG. 1, in some embodiments, the bottom electrode 110, the barrier layers 120a and 120b, the inserting layer 125a, the dielectric layer 130a and 130b, and the top electrode 150 may be sequentially deposited by a physical vapor deposition (PVD) process, a chemical vapor deposition (CVD) process (e.g., low-pressure CVD (LPCVD) and/or plasma-enhanced CVD (PECVD), among other examples), an atomic layer deposition (ALD) process, and/or another suitable deposition process.

In some embodiments where the dielectric layers 130a and 130b are made of hafnium oxide (HfO₂) doped with zirconium (Zr), the dielectric layers 130a and 130b can be formed using an ALD process. The ALD process may include alternately performing several hafnium oxide (HfO₂) deposition cycles and zirconium oxide (ZrO₂) deposition cycles in an alternate manner, until each of the dielectric layers 130a and 130b achieve the desired thickness, for example, about 5 nm.

In some embodiments, where the barrier layers 120a and 120b are made of aluminum oxide (AlOₓ), the barrier layers 120a and 120b can be formed using an ALD process. The barrier layers 120a and 120b are located vertically adjacent to the bottom electrode 110 and the top electrode 150, respectively, which can suppress the leakage current due to the property of wide band gap and surface shallow trap improvement. Furthermore, the barrier layer 120a serves as a barrier to suppress the diffusion between the bottom electrode 110 and the dielectric layer 130a. Similarly, the barrier layer 120b serves as a barrier to suppress the diffusion between the top electrode 150 and the dielectric layer 130b.

In some embodiments, where the inserting layer 125a is made of aluminum oxide (AlOₓ), the inserting layer 125a can be formed using an ALD process. As shown in FIG. 1, the inserting layer 125a separates the dielectric layer 130a from the dielectric layer 130b, so as to reduce the effective thickness, stack leakage, and monoclinic phase ratio. Moreover, the barrier layer 120a, the barrier layer 120b, and the inserting layer 125a stabilize the phase transition for morphotropic phase boundary (MPB). In some embodiments, if the inserting layer 125a is absent, the dielectric layer 130a will be in contact with dielectric layer 130b, resulting in a thicker composite dielectric layer. However, if the dielectric layer (e.g., HfZrO) is excessively thick, the dielectric layer tends to include more monoclinic phase in the crystalline structure of the dielectric layer, while the monoclinic phase may reduce the ferroelectric property of the dielectric layer, which is undesirable for the capacitor structure.

In some embodiments, the barrier layer 120a and the barrier layer 120b may have the same thickness. In some embodiments, the thickness of the barrier layer 120a and the barrier layer 120b is different from the thickness of the inserting layer 125a. In some embodiments, the thickness of the barrier layer 120a and the barrier layer 120b is greater than the thickness of the inserting layer 125a. This is because the inserting layer 125a, as mentioned above, is used to separate the dielectric layers 130a and 130b, and thus the inserting layer 125a does not require excessive thickness.

Although only planar-type capacitors are illustrated above in FIG. 1, the spirit of the present disclosure can also be applied to capacitors with different designs such as cylinder-type capacitors or pedestal-type capacitors.

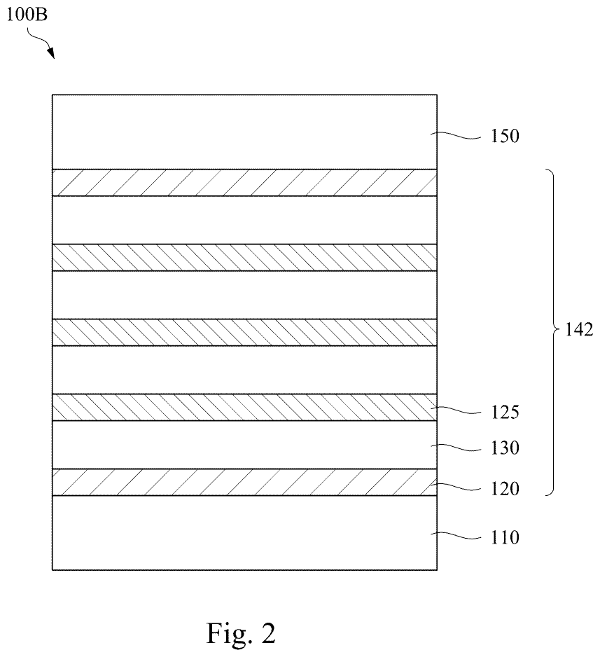

FIG. 2 is a schematic diagram depicting a capacitor structure according to some embodiments of the present disclosure. Referring to FIG. 2, a capacitor structure 100B includes a bottom electrode 110, a dielectric structure 142 over the bottom electrode 110, and a top electrode 150 over the dielectric structure 142. The capacitor structure 100B shown in FIG. 2 is similar to the capacitor structure 100A shown in FIG. 1. Components that are the same or similar to those in FIG. 1 and FIG. 2 are given the same reference numbers, and detailed description thereof is thus omitted.

The dielectric structure 142 may be a multi-layer structure in which a plurality of dielectric layers are stacked. The dielectric structure 142 in the capacitor structure 100B may include barrier layers 120, dielectric layers 130, and inserting layers 125 that are alternately stacked over the bottom electrode 110. For example, the dielectric structure 140 is illustrated as including two layers of barrier layers 120, four layers of dielectric layers 130, and three layers of inserting layers 125 for illustrative purposes. It is appreciated that any number of the inserting layers 125 and the dielectric layers 130 can be included in the dielectric structure 142. As shown in FIG. 2, the dielectric layers 130 may be separated in a vertical direction by the inserting layers 125. Furthermore, the barrier layers 120 are adjacent to the bottom electrode 110 and the top electrode 150.

In some embodiments, the barrier layers 120 and the inserting layers 125 may include the same high-k dielectric material, such as aluminum oxide (AlOₓ). In some embodiments, the dielectric layers 130 may include high-k dielectric material, such as hafnium oxide (HfO₂). In some embodiments, the dielectric layers 130 (e.g., HfO₂) may be doped with zirconium (Zr) at a concentration between about 50% to about 100% (e.g., 70%). In some embodiments, the barrier layers 120 and the inserting layers 125 may be free of zirconium. That is, the zirconium concentration in the barrier layers 120 and the inserting layers 125 may be lower than the zirconium concentration in the dielectric layers 130.

The dielectric layers 130 have crystalline structures with orthogonal phase and tetragonal phase. In some embodiments, by doping the dielectric layers 130 with zirconium, the dielectric layers 130 may have a material having a composition of the morphotropic phase boundary (MPB) between an orthogonal phase and a tetragonal phase, thereby gain the condition equivalent oxide thickness (EOT) due to the higher k-value to achieve an increasing capacitance and to reduce leakage current.

The fabrication method results in the capacitor structure 100B will be described in further detail below. As shown in FIG. 2, in some embodiments, the bottom electrode 110, the barrier layers 120, the inserting layers 125, the dielectric layers 130, and the top electrode 150 may be sequentially deposited by a physical vapor deposition (PVD) process, a chemical vapor deposition (CVD) process (e.g., low-pressure CVD (LPCVD) and/or plasma-enhanced CVD (PECVD), among other examples), an atomic layer deposition (ALD) process, and/or another suitable deposition process.

In some embodiments where the dielectric layers 130 are made of hafnium oxide (HfO₂) doped with zirconium (Zr), the dielectric layers 130 can be formed using an ALD process. The ALD process may include alternately performing several hafnium oxide (HfO₂) deposition cycles and zirconium oxide (ZrO₂) deposition cycles in an alternate manner, until the dielectric layers 130a and 130b achieve the desired thickness.

In some embodiments, where the barrier layers 120 are made of aluminum oxide (AlOₓ), the barrier layers 120 can be formed using an ALD process. The barrier layers 120 are located vertically adjacent to the bottom electrode 110 and the top electrode 150, which can enhance the ferroelectric property of the dielectric layers 130 and decrease the leakage current due to the property of wide band gap and surface shallow trap improvement. Furthermore, the barrier layer 120 serves as a barrier to suppress the diffusion between the bottom electrode 110 and the dielectric layer 130 and the diffusion between the top electrode 150 and the dielectric layer 130.

In some embodiments, where the inserting layers 125 are made of aluminum oxide (AlOₓ), the inserting layers 125 can be formed using an ALD process. As shown in FIG. 2, the inserting layers 125 separates the dielectric layers 130 from each other, so as to reduce the effective thickness of the dielectric layers 130, stack leakage, and monoclinic phase ratio. Moreover, the barrier layers 120 and the inserting layers 125 stabilize the phase transition for morphotropic phase boundary (MPB).

In some embodiments, the thickness of each barrier layer 120 is different from the thickness of each inserting layer 125. In some embodiments, the thickness of each barrier layer 120 is greater than the thickness of each inserting layer 125.

In FIG. 2, the multi-stack cell structure of the capacitor structure 100B might further improve the MBP transition by reduction of effective thickness and decrease the leakage current by multi-AlOₓ thin film.

Although only planar-type capacitors are illustrated above in FIG. 2, the spirit of the present disclosure can also be applied to capacitors with different designs such as cylinder-type capacitors or pedestal-type capacitors.

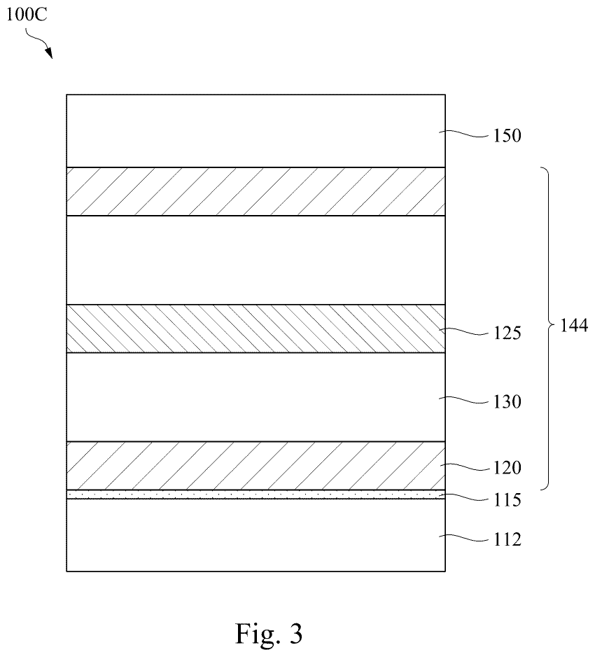

FIG. 3 is a schematic diagram depicting a capacitor structure according to some embodiments of the present disclosure. Referring to FIG. 3, a capacitor structure 100C includes a bottom electrode 112, an oxide layer 115 over the bottom electrode 112, a dielectric structure 144 over the oxide layer 115, and a top electrode 150 over the dielectric structure 144. The capacitor structure 100C shown in FIG. 3 is similar to the capacitor structure 100A and the capacitor structure 100B shown in FIG. 1 and FIG. 2. Throughout the description herein, unless otherwise specified, the same reference numeral in different figures refers to the same or similar component formed by a same or similar method using a same or similar material(s).

In some embodiments, a material of the bottom electrode 112 may be different from a material of the top electrode 150. For example, the bottom electrode 112 may include polysilicon (poly-Si) and the top electrode may include titanium nitride (TiN). In some embodiments, the oxide layer 115 may formed of silicon oxide (SiO₂).

The dielectric structure 144 may be a multi-layer structure in which a plurality of dielectric layers are stacked. The dielectric structure 144 in the capacitor structure 100C may include barrier layers 120, dielectric layers 130, and inserting layers 125 that are alternately stacked over the oxide layer 115. For example, the dielectric structure 144 is illustrated as including two layers of barrier layers 120, two layers of dielectric layers 130, and one layer of inserting layer 125 for illustrative purposes. It is appreciated that any number of the inserting layers 125 and the dielectric layers 130 can be included in the dielectric structure 144. As shown in FIG. 3, the dielectric layers 130 may be separated in a vertical direction by the inserting layers 125. Furthermore, the barrier layers 120 are adjacent to the oxide layer 115 and the top electrode 150.

In some embodiments, the barrier layers 120 and the inserting layers 125 may include the same high-k dielectric material, such as aluminum oxide (AlOₓ). In some embodiments, the dielectric layers 130 may include high-k dielectric material, such as hafnium oxide (HfO₂). In some embodiments, the dielectric layers 130 (e.g., HfO₂) may be doped with zirconium (Zr) at a concentration between about 50% to about 100% (e.g., 70%). In some embodiments, the barrier layers 120 and the inserting layers 125 may be free of zirconium. That is, the zirconium concentration in the barrier layers 120 and the inserting layers 125 may be lower than the zirconium concentration in the dielectric layers 130.

The dielectric layers 130 have crystalline structures with orthogonal phase and tetragonal phase. In some embodiments, by doping the dielectric layers 130 with zirconium, the dielectric layers 130 may have a material having a composition of the morphotropic phase boundary (MPB) between an orthogonal phase and a tetragonal phase, thereby gain the condition equivalent oxide thickness (EOT) due to the higher k-value to achieve an increasing capacitance and to reduce leakage current.

The fabrication method results in the capacitor structure 100C will be described in further detail below. As shown in FIG. 3, in some embodiments, the bottom electrode 112, the barrier layers 120, the inserting layers 125, the dielectric layers 130, and the top electrode 150 may be sequentially deposited by a physical vapor deposition (PVD) process, a chemical vapor deposition (CVD) process (e.g., low-pressure CVD (LPCVD) and/or plasma-enhanced CVD (PECVD), among other examples), an atomic layer deposition (ALD) process, and/or another suitable deposition process.

In some embodiments where the dielectric layers 130 are made of hafnium oxide (HfO₂) doped with zirconium (Zr), the dielectric layers 130 can be formed using an ALD process. The ALD process may include alternately performing several hafnium oxide (HfO₂) deposition cycles and zirconium oxide (ZrO₂) deposition cycles in an alternate manner, until the dielectric layers 130a and 130b achieve the desired thickness.

In some embodiments, where the barrier layers 120 are made of aluminum oxide (AlOₓ), the barrier layers 120 can be formed using an ALD process. The barrier layers 120 are located vertically adjacent to the bottom electrode 112 and the top electrode 150, which can enhance the ferroelectric property of the dielectric layers 130 and decrease the leakage current due to the property of wide band gap and surface shallow trap improvement. Furthermore, the barrier layer 120 serves as a barrier to suppress the diffusion between the top electrode 150 and the dielectric layer 130.

In some embodiments, where the inserting layers 125 are made of aluminum oxide (AlOₓ), the inserting layers 125 can be formed using an ALD process. As shown in FIG. 3, the inserting layers 125 separates the dielectric layers 130 from each other, so as to reduce the effective thickness of the dielectric layers 130, stack leakage, and monoclinic phase ratio. Moreover, the barrier layers 120 and the inserting layers 125 stabilize the phase transition for morphotropic phase boundary (MPB).

In some embodiments, during the ALD process forming the barrier layer 120 over the bottom electrode 112, oxygen source and aluminum source may be supplied into a deposition chamber with carrier gas. In such embodiments, the oxygen source may oxidize top portion of the bottom electrode which is made of polysilicon during the ALD process, and then results in the formation of the oxide layer 115. In some embodiments, the oxide layer 115 may include silicon oxide (SiO₂). Furthermore, after the formation of the oxide layer 115, the thickness of the bottom electrode 112 decreased. In some embodiments, the oxygen source may include oxygen (O₂), ozone (O₃), water (H₂O), or other suitable oxygen source, and the aluminum source may include trimethylaluminum (TMA), aluminum chloride, or other suitable aluminum source.

In some embodiments, oxidize the bottom electrode 112 by providing the oxygen source, such as oxygen (O₂), ozone (O₃), water (H₂O), or other suitable oxygen source, to form the oxide layer 115 over the bottom electrode 112. In some embodiments, the oxide layer 115 may include silicon oxide (SiO2). Furthermore, after the formation of the oxide layer 115, the thickness of the bottom electrode 112 decreased.

In some embodiments, the thickness of each barrier layer 120 is different from the thickness of each inserting layer 125. In some embodiments, the thickness of each barrier layer 120 is greater than the thickness of each inserting layer 125. In some embodiments, the oxide layer 115 is the thinnest layer in the dielectric structure 144.

In FIG. 3, the multi-stack cell structure of the capacitor structure 100C might further improve the MBP transition by reduction of effective thickness and decrease the leakage current by multi-AlOₓ thin film.

Although only planar-type capacitors are illustrated above in FIG. 3, the spirit of the present disclosure can also be applied to capacitors with different designs such as cylinder-type capacitors or pedestal-type capacitors.

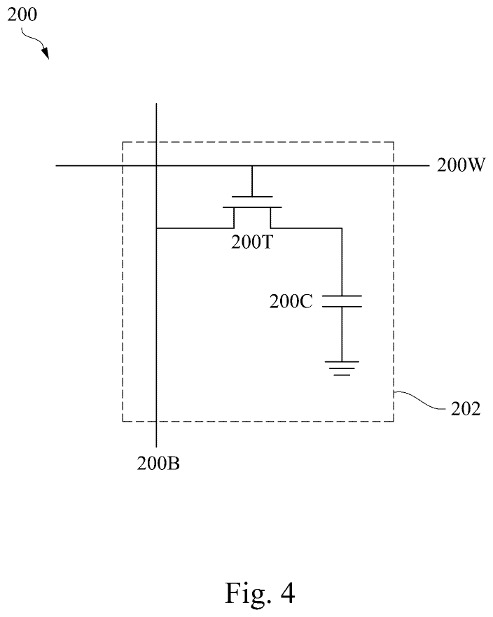

FIG. 4 is a circuit diagram of a memory cell of a memory device, according to some embodiments of the present disclosure. With reference to FIG. 4, a memory device 200 consists of multiple memory cells 202 arranged in a rectangular matrix configuration. In some embodiments, the memory device 200 is a dynamic random access memory (DRAM) device. The memory cell 202 of the memory device 200 consists of a transistor 200T and a capacitor 200C electrically connected to the transistor 200T as main structures. The one side of capacitor 200C is coupled with the drain region of the transistor 200T and the other side of the capacitor 200C is coupled to the ground. The memory device 200 further includes a word line 200W coupled with the gate region of the transistor 200T, and a bit line 200B coupled with the source of the transistor 200T.

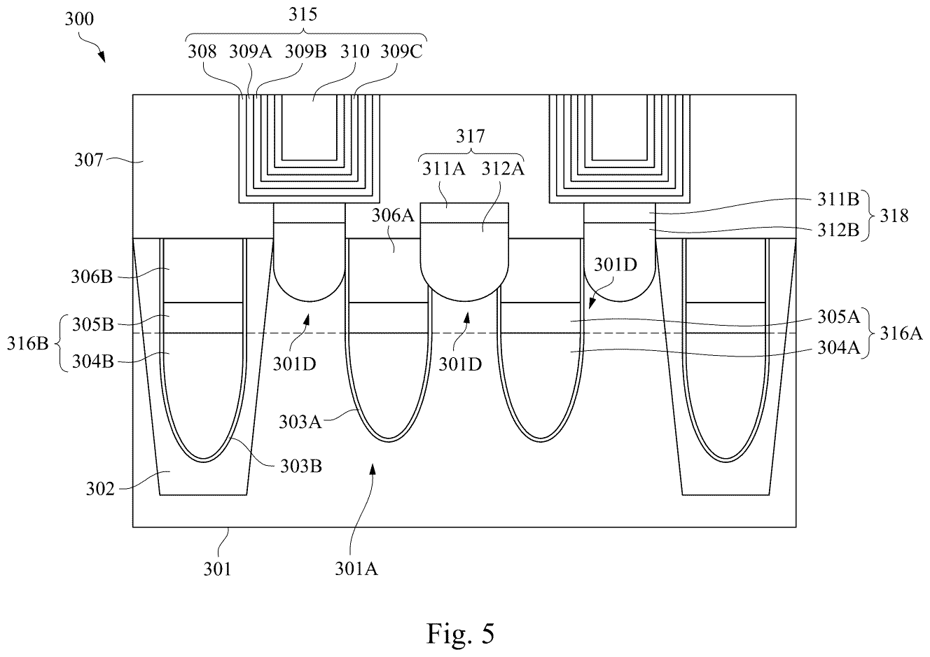

FIG. 5 is a cross-sectional view of a memory device according to some embodiments of the present disclosure. Shown there is a memory device 300. In some embodiments, the cross-sectional view of the memory device 300 may be an example of the memory device 200 as discussed in FIG. 4.

The memory device 300 includes a substrate 301. In some embodiments, the substrate 301 can be suitable semiconductive material, such as silicon, silicon carbide, gallium arsenic, gallium phosphide, germanium, indium antimonide, indium phosphide, indium arsenide, or the like. The substrate 301 may also be doped with suitable dopants. For example, the substrate 301 may be doped with p-type dopants, such as boron (B), gallium (Ga), indium (In), aluminium (Al), or the like. In other embodiments, the substrate 301 may be doped with n-type dopants, such as phosphorus (P), arsenic (As), or antimony (Sb), or the like.

Isolation structures 302 are disposed within the substrate 301. The isolation structures 302 can be suitable isolation structures, such as shallow trench isolation (STI) structures. In the cross-sectional view of FIG. 5, shown there are two isolation structures 302 that define an active area 301A where at least one transistor is formed thereon. In some embodiments, the isolation structures 302 may be made of suitable dielectric material, such as silicon oxide, silicon nitride or the like.

The memory device 300 further includes a plurality of word line structures 316A and 316B. In greater detail, in the cross-sectional view of FIG. 5, the word line structures 316A are embedded in the active area 301A of the substrate 301, while the word line structures 316B are embedded in the isolation structures 302.

The memory device 300 further includes dielectric layers 306A over the respective word line structures 316A, and dielectric liners 303A lining the respective word line structures 316A and the respective dielectric layers 306A. In some embodiments, the dielectric layers 306A may include suitable dielectric material, such as silicon oxide, silicon nitride or the like. In some embodiments, the dielectric liners 303A may include suitable dielectric material, such as silicon oxide, silicon nitride or the like.

Similarly, the memory device 300 further includes dielectric layers 306B over the respective word line structures 316B, and dielectric liners 303B lining the respective word line structures 316B and the respective dielectric layers 306B. The materials of the dielectric layers 306B and the dielectric liners 303B may be similar to those described with respect to the dielectric layers 306A and the dielectric liners 303A, and thus relevant details will not be repeated for brevity.

In some embodiments, each of the word line structures 316A includes a bottom conductive material 304A and a top conductive material 305A over the bottom conductive material 304A. In some embodiments, the bottom conductive material 304A and the top conductive material 305A are made of different materials. In some embodiments, the bottom conductive material 304A may include suitable conductive material, such as cobalt, nickel, titanium, titanium nitride, tungsten, tungsten nitride, the like, or the combination thereof. For example, in some embodiments, the combination of titanium nitride and tungsten are used as the bottom conductive material 304A. In some embodiments, the top conductive material 305A may be suitable material to reduce the band-bending between the active area 301A and the dielectric liner 303A. The top conductive material 305A may be a semiconductive material or conductive material. In some embodiments, polysilicon is used for the top conductive material 305A. In some other embodiments, doped polysilicon is used for the top conductive material 305A. Although the top conductive material 305A is illustrated having a rectangular cross-section, the present disclosure is not limited thereto. In other embodiments, the cross-section of the top conductive material 305A can also be half-circle, triangle, trapezoid, reverse-trapezoid, irregular.

With respect to the word line structures 316B, each of the word line structures 316B includes a bottom conductive material 304B and a top conductive material 305B over the bottom conductive material 304B. The materials of the bottom conductive material 304B and the top conductive material 305B may be similar to those described with respect to the bottom conductive material 304A and the top conductive material 305A, and thus relevant details will not be repeated for brevity.

The memory device 300 further includes doped regions 301D within the active area 301A of the substrate 301, in which a pair of doped regions 301D are disposed on opposite sides of the word line structures 316A. In some embodiments, the doped regions 301D may include opposite conductivity type than the substrate 301. For example, when the substrate 301 is a p-type substrate, the doped regions 301D may be n-type doped regions. Similarly, when the substrate 301 is an n-type substrate, the doped regions 301D may be p-type doped regions.

Here, the word line structure 316A, the dielectric liner 303A, the pair of doped regions 301D on opposite sides of the word line structure 316A, and the active area 301A of the substrate 301 may collective serve as the transistor of the memory device 300 (e.g. the transistor 200T of FIG. 4). In greater detail, the word line structure 316A may serve as the gate electrode of the transistor, the dielectric liner 303A may serve as the gate dielectric of the transistor, the active area 301A of the substrate 301 may serve as the channel region of the transistor, and the doped regions 301D may serve as source/drain regions of the transistor.

The memory device 300 further includes a bit line structure 317 over the substrate 301 and electrically coupled with one of the doped regions 301D. In some embodiments, the bit line structure 317 may include a buried contact 312A and a bit line 311A over the buried contact 312A. In some embodiments, the buried contact 312A has a portion embedded in the substrate 301 and a portion protruding from the substrate 301. In some embodiments, a material of the buried contact 312A may be doped silicon or polysilicon. In some embodiments, a material of the bit line 311A may be suitable conductive material, such as tungsten, tungsten nitride, titanium nitride, the like, or the combination thereof.

The memory device 300 further includes capacitor contact structures 318 over the substrate 301 and electrically coupled with the doped regions 301D. In some embodiments, each of the capacitor contact structures 318 may include a buried contact 312B and a metal contact 311B over the buried contact 312B. In some embodiments, the buried contact 312B has a portion embedded in the substrate 301 and a portion protruding from the substrate 301. In some embodiments, the materials of the buried contact 312B and the metal contact 311B may be similar to those described with respect to the buried contact 312A and bit line 311A, and thus relevant details will not be repeated for brevity.

The memory device 300 further includes capacitor structures 315 over the respective capacitor contact structures 318. In some embodiments, each of the capacitor structures 315 includes a lower electrode 308, barrier layers 309A, dielectric layers 309B, inserting layers 309C and an upper electrode 310, in which the barrier layers 309A, the dielectric layers 309B, and inserting layers 309C are disposed between the upper electrode 310 and the lower electrode 308. In some embodiments, the lower electrode 308, the barrier layers 309A, the dielectric layers 309B, and the inserting layers 309C may include U-shape cross-section.

The capacitor structures 315 of FIG. 5 may be similar to the capacitor structure 10 as discussed in FIGS. 1-3. In greater detail, the lower electrode 308, the barrier layers 309A, the dielectric layers 309B, the inserting layers 309C, and the upper electrode 310 of the capacitor structures 315 may include similar materials and formation methods as the bottom electrode 110 or 112, the barrier layers 120, the dielectric layers 130, the inserting layers 125, and the top electrode 150 of the capacitor structures 100A-100C, respectively. Accordingly, relevant details will not be repeated for brevity.

The memory device 300 further includes a dielectric layer 307 over the substrate 301 and laterally surrounding the bit line structure 317, the capacitor contact structures 318, and the capacitor structures 315. In some embodiments, the dielectric layer 307 may be formed of, for example, silicon oxide, borophosphosilicate glass, undoped silicate glass, fluorinated silicate glass, low-k dielectric materials, the like, or a combination thereof.

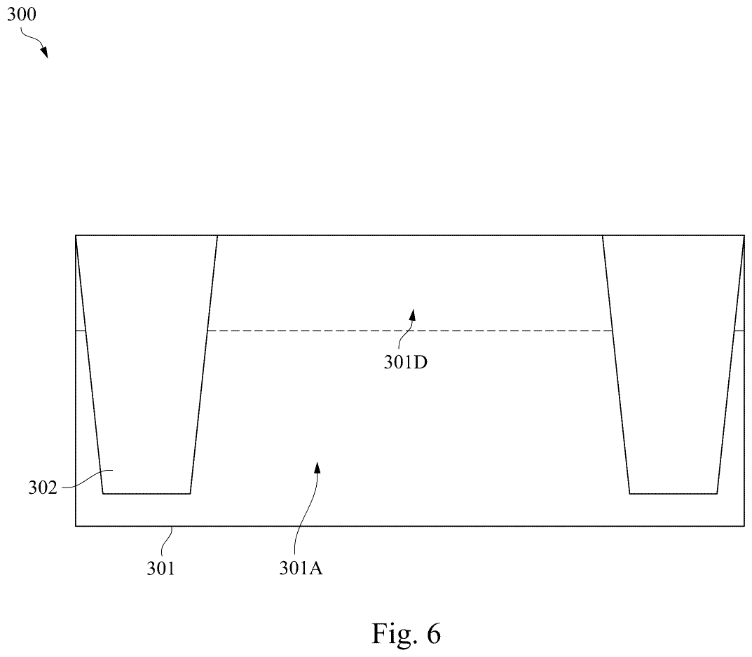

FIGS. 6 to 14 are cross-sectional views at various stages of forming a memory device according to some embodiments in the present disclosure. In greater detail, FIGS. 6 to 14 illustrate a method for forming the memory device 300 as discussed in FIG. 5. Accordingly, similar elements are labeled the same, and relevant details will not be repeated for brevity.

Referring to FIG. 6, a substrate 301 is provided. Isolation structures 302 are formed in the substrate 301 to define an active area 301A. For example, a series of deposition processes may be performed to deposit a pad oxide layer (not shown) and a pad nitride layer (not shown) over the substrate 301. A photolithography process may be performed to define the positions of the isolation structures 302. After the photolithography process, an etch process, such as an anisotropic dry etch process, may be performed to form trenches penetrating through the pad oxide layer, the pad nitride layer, and the substrate 301. In some embodiments, the cleaning process may be performed by suitable cleaning method, such as wet clean. An insulating material may be deposited into the trenches and a planarization process, such as chemical mechanical polishing, may be subsequently performed to remove excess filling material until the substrate 301 is exposed. After the isolation structures 302 are formed, a doped region 301D may be formed within the active area 301A of the substrate 301 through an implantation process.

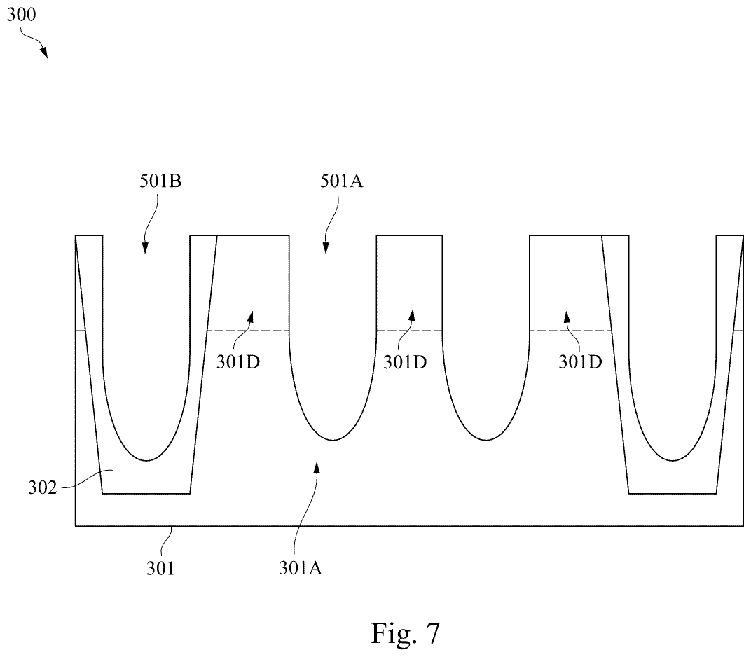

Referring to FIG. 7, trenches 501A and 501B are formed in the substrate 301 and the isolation structures 302, respectively. In some embodiments, a patterned mask (e.g., photoresist) is formed over the substrate 301, in which the patterned mask may include openings that define the positions of the trenches 501A and 501B. Afterwards, an etching process may be performed from the openings of the patterned mask to remove portions of the substrate 301 and the isolation structures 302, so as to form the trenches 501A and 501B. In some embodiments, the etching process may be suitable etching process, such as wet etch or dry etch. In some embodiments, the anisotropic etching process may be performed, such as RIE, DRIE, or the like. In some embodiments, the aspect ratio of trench 501A may be different from (or the same as) the aspect ratio of trench 501B.

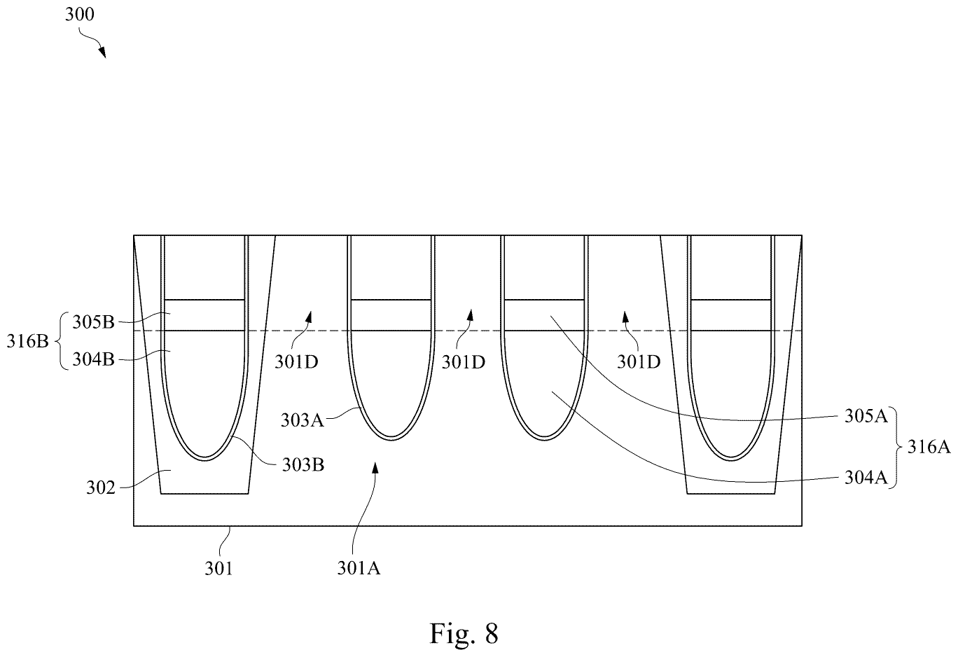

Referring to FIG. 8, dielectric liners 303A and word line structures 316A are formed in the trenches 501A, and the dielectric liners 303B and word line structures 316B are formed in the trenches 501B, respectively. The word line structure 316A includes a bottom conductive material 304A and a top conductive material 305A over the bottom conductive material 304A. The word line structure 316B includes a bottom conductive material 304B and a top conductive material 305B over the bottom conductive material 304B.

In some embodiments, a first deposition process may be performed to form a material of the dielectric liner 303A and 303B over the substrate 301 and lining sidewalls of the trenches 501A and 501B. In some embodiments, the first deposition process may be suitable deposition method, such as CVD, PECVD, low pressure CVD (LPCVD), ultra-high vacuum CVD (UHVCVD), atomic layer deposition (ALD), or the like.

Afterwards, a second deposition process may be performed to form a material of the bottom conductive materials 304A and 304B over the substrate 301 and overfilling the trenches 501A and 501B. Then, an etching back process is performed to lower top surface of the material of the bottom conductive materials 304A and 304B.

Then, a third deposition process may be performed to form a material of the top conductive materials 305A and 305B and overfilling the trenches 501A and 501B.

After the deposition process, a planarization process, such as CMP, may be performed on the material of the top conductive materials 305A and 305B until the substrate 301 is exposed. As a result, a top surface of the substrate 301, a top surface of top conductive material 305A, a top surface of top conductive material 305B, and a top surface of isolation structure 302 are substantially coplanar. In some embodiments, a cleaning process may be performed after the planarization process.

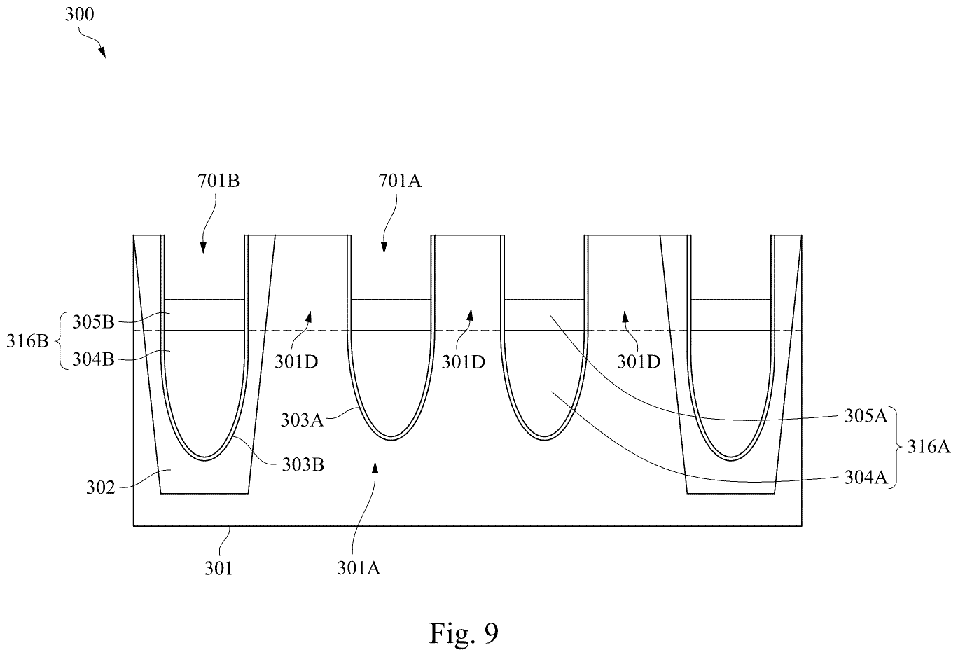

Referring to FIG. 9, an etching back process may be performed to lower top surfaces of the top conductive materials 305A and 305B to form recesses 701A and 701B over the word line structures 316A and 316B, respectively.

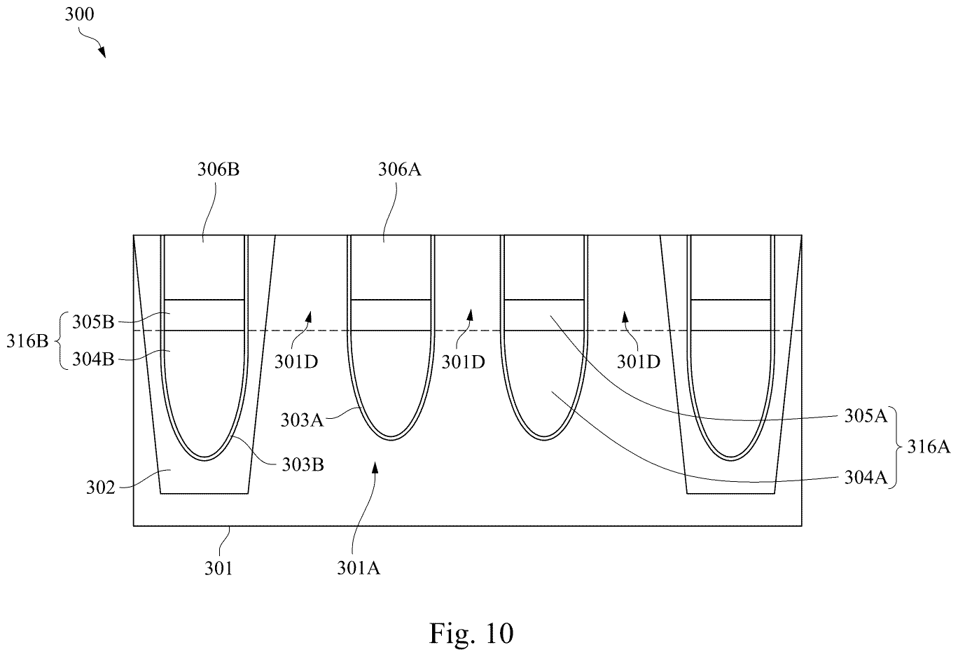

Referring to FIG. 10, dielectric layers 306A and 306B are formed over the word line structures 316A and 316B, respectively. In some embodiments, a deposition process may be performed to form a dielectric material over the substrate 301 and covering the word line structures 316A and 316B. Then, a planarization process may be performed to remove excess dielectric material until the substrate 301 is exposed. In some embodiments, the planarization process may be performed to make a top surface of the dielectric layer 306A and the top surface of the dielectric layer 306B coplanar with the surface of the substrate 301.

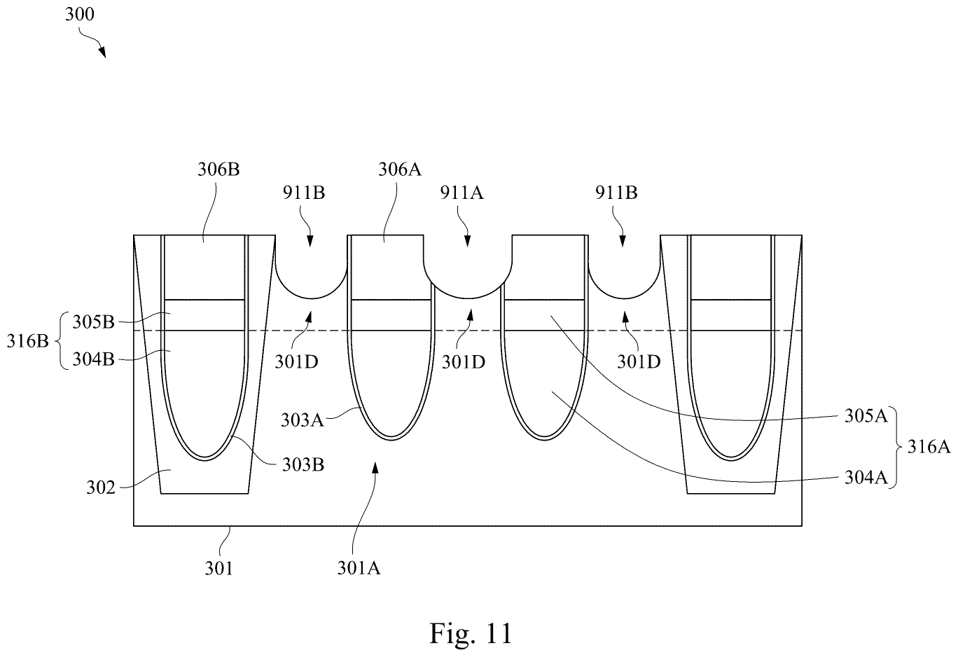

Referring to FIG. 11, recesses 911A and recesses 911B are formed in the doped regions 301D of the substrate 301. In some embodiments, the bottom of the recesses 911A and 911B may be higher than the top surface of the top conductive material 305A. In some embodiments, a patterned mask (not shown) is formed over the substrate 301, and an etching process is performed to remove portions of the substrate 301 exposed through the patterned mask to form the recesses 911A and 911B. In some embodiments, a clean process may be performed after the etching process. In some embodiments, the recess 911A may be formed between adjacent dielectric layers 306A. In some embodiments, the recess 911B may be formed between adjacent dielectric layers 306A and 306B.

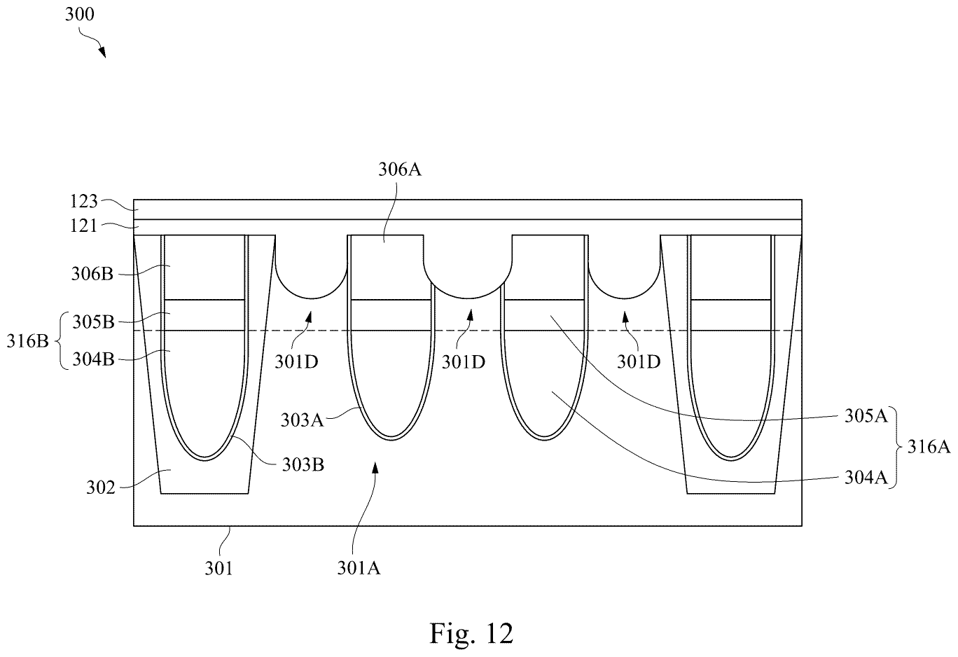

Referring to FIG. 12, a first conductive layer 121 is formed over the substrate 301, and a second conductive layer 123 is formed over the first conductive layer 121. In some embodiments, the first conductive layer 121 may fill the recesses 911A and 911B and may be in contact with the doped regions 301D. In some embodiments, the first conductive layer 121 and the second conductive layer 123 may be formed using suitable deposition process.

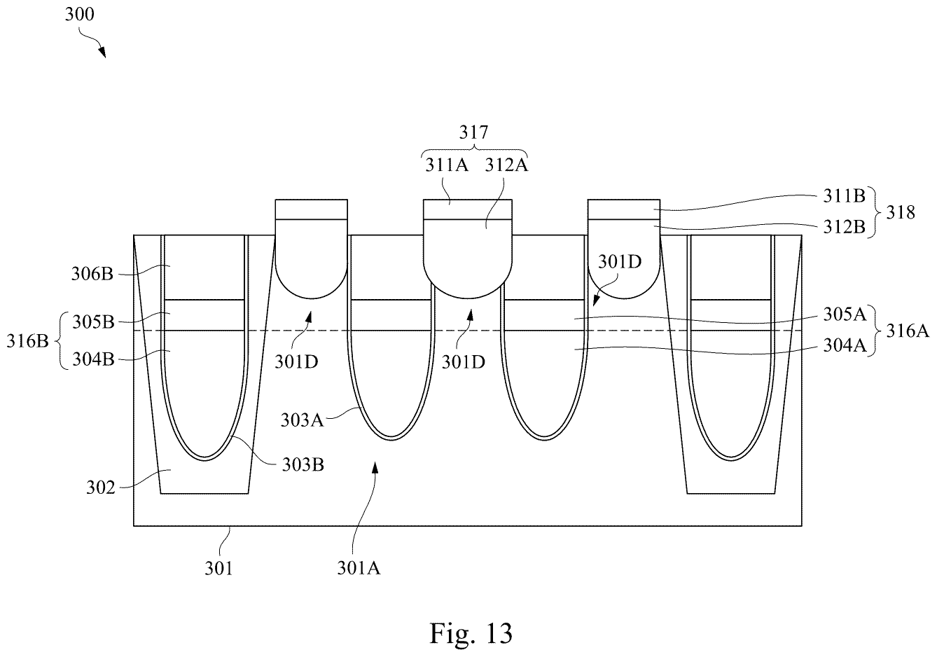

Referring to FIG. 13, the first conductive layer 121 and the second conductive layer 123 are patterned to form a bit line structure 317 and capacitor contact structures 318. In some embodiments, the bit line structure 317 includes a buried contact 212A and bit line 211A over the buried contact 212A, in which the buried contact 212A is a remaining portion of the first conductive layer 121, and the bit line 211A is a remaining portion of the second conductive layer 123. On the other hand, the capacitor contact structures 318 includes a buried contact 212B and metal contact 211B over the buried contact 212B, in which the buried contact 212B is a remaining portion of the first conductive layer 121, and the metal contact 211B is a remaining portion of the second conductive layer 123.

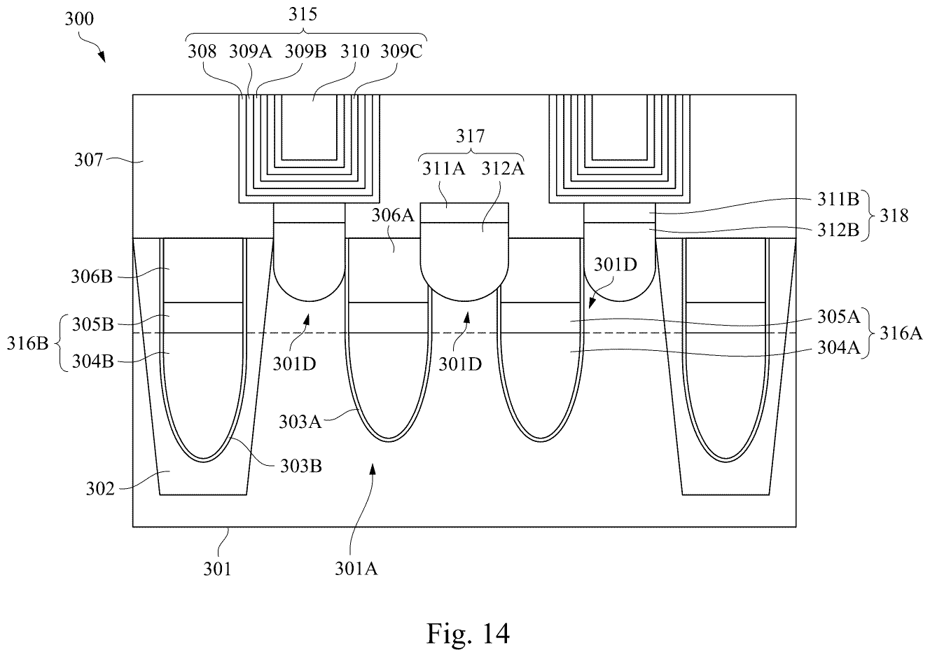

Referring to FIG. 14, a dielectric layer 307 is formed over the substrate 301 and covering the bit line structure 317 and capacitor contact structures 318. Then, capacitor structures 315 are formed in the dielectric layer 307 and in contact with the respective capacitor contact structures 318. In some embodiments, the dielectric layer 307 may be formed using suitable deposition process. In some embodiments, the capacitor structures 315 may be formed by, for example, patterning the dielectric layer 307 to forming openings exposing the capacitor contact structures 318, depositing a lower electrode 308, barrier layers 309A, dielectric layers 309B, inserting layers 309C and an upper electrode 310 in the openings by ALD process, and then performing a planarization process until the dielectric layer 307 exposed.

In some embodiments, additional processes and steps may be performed to accomplish the fabrication process of the memory device. In some embodiments, additional back end of line (BEOL) processes may be performed on the memory device 300.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A memory device, comprising:
a substrate; and
a capacitor structure over the substrate, comprising:
a bottom electrode;
a dielectric structure over the bottom electrode, comprising:
a bottom barrier layer made of aluminum oxide;
a top barrier layer made of aluminum oxide over the bottom barrier layer; and
a stack of dielectric layers made of zirconium-doped hafnium oxide and at least one inserting layer made of aluminum oxide between the bottom barrier layer and the top barrier layer, wherein the at least one inserting layer is between adjacent two of the dielectric layers; and
a top electrode over the dielectric structure.

2. The memory device of claim 1, wherein a zirconium concentration of the dielectric layers is from about 50% to about 100%.

3. The memory device of claim 1, wherein the bottom barrier layer and the top barrier layer are in contact with the bottom electrode and the top electrode, respectively.

4. The memory device of claim 1, wherein the bottom electrode and the top electrode are made of titanium nitride.

5. The memory device of claim 1, wherein the bottom electrode is made of polysilicon, and the top electrode is made of titanium nitride.

6. The memory device of claim 5, further comprising a silicon oxide layer between the bottom electrode and the bottom barrier layer.

7. The memory device of claim 1, wherein the bottom barrier layer and the top barrier layer are thicker than the at least one inserting layer.

8. The memory device of claim 1, wherein the dielectric structure comprises a plurality of inserting layers, wherein each of the plurality of inserting layers is between adjacent two of the dielectric layers.

9. The memory device of claim 1, wherein the dielectric layers have crystalline structures with tetragonal phase and orthorhombic phase.

10. The memory device of claim 1, further comprising:
a word line structure over the substrate; and
a bit line structure over the substrate and electrically connected to a doped region of the substrate on a first side of the word line structure, wherein the capacitor structure is electrically connected to another doped region of the substrate on a second side of the word line structure.

11. A method for forming a memory device, comprising:
forming a capacitor structure over a substrate, comprising:
forming a bottom electrode;
forming a dielectric structure over the bottom electrode, comprising:
forming a bottom barrier layer made of aluminum oxide;
forming a stack of dielectric layers made of zirconium-doped hafnium oxide and at least one inserting layer made of aluminum oxide over the bottom barrier layer, wherein the at least one inserting layer is between adjacent two of the dielectric layers; and
forming a top barrier layer made of aluminum oxide over the stack of the dielectric layers and the at least one inserting layer; and
forming a top electrode over the dielectric structure.

12. The method of claim 11, wherein a zirconium concentration of the dielectric layers is from about 50% to about 100%.

13. The method of claim 11, wherein the bottom barrier layer and the top barrier layer are in contact with the bottom electrode and the top electrode, respectively.

14. The method of claim 11, wherein the bottom electrode and the top electrode are made of titanium nitride.

15. The method of claim 11, wherein the bottom electrode is made of polysilicon, and the top electrode is made of titanium nitride.

16. The method of claim 15, further comprising:
oxidizing a portion of the bottom electrode into an oxide layer.

17. The method of claim 16, wherein the oxide layer includes silicon oxide.

18. The method of claim 15, wherein forming the bottom barrier layer comprises performing an ALD process by providing an oxygen source and an aluminum source, and wherein the oxygen source oxidizes a portion of the bottom electrode into an oxide layer.

19. The method of claim 11, wherein the bottom barrier layer and the top barrier layer are thicker than the at least one inserting layer.

20. The method of claim 11, further comprising:
forming a word line structure over the substrate; and
forming a bit line structure over the substrate and electrically connected to a doped region of the substrate on a first side of the word line structure, wherein the capacitor structure is electrically connected to another doped region of the substrate on a second side of the word line structure.
